(19) United States
(12) Patent Application Publication
(10) Pub. No.: US 2023/0081962 A1
(43) Pub. Date: Mar. 16, 2023

(54) METHOD FOR FORMING GRAPHENE BARRIER LAYER FOR SEMICONDUCTOR DEVICE AND CONTACT STRUCTURE FORMED BY THE SAME

(71) Applicant: WONIK IPS CO., LTD., Pyeongtaek-si Gyeonggi-do (KR)

(72) Inventors: Hong Ki PARK, Hanam-si Gyeonggi-do (KR); Jin Ho JEON, Hwaseong-si Gyeonggi-do (KR); Won Jun YOON, Seoul (KR); Tae Sung KIM, Hwaseong-si Gyeonggi-do (KR); Woo Hoon SUN, Osan-si Gyeonggi-do (KR); Dong Woo KIM, Seoul (KR); Keon Jung LEE, Osan-si Gyeonggi-do (KR); Jee Hye PARK, Osan-si Gyeonggi-do (KR)

(73) Assignee: WONIK IPS CO., LTD., Pyeongtaek-si Gyeonggi-do (KR)

(21) Appl. No.: 17/899,296

(22) Filed: Aug. 30, 2022

(30) Foreign Application Priority Data
Sep. 8, 2021 (KR) 10-2021-0119637

(51) Int. Cl. H01L 23/532; H01L 21/768

(52) U.S. Cl. CPC H01L 23/53266; H01L 21/76846

(57) ABSTRACT

Various embodiments generally relate to a method for forming a graphene barrier layer for a semiconductor device, and more particularly, to a method of forming a barrier thin film including a graphene layer capable of reducing the contact resistance of a metal interconnect. A method for forming a graphene barrier layer according to an embodiment includes: loading a substrate, which has a titanium-containing layer formed thereon, in a chamber of a substrate processing system, the chamber having a processing space formed therein; inducing nucleation on the titanium-containing layer by supplying a first reactant gas including a unsaturated hydrocarbon into the chamber; and forming a graphene layer on the titanium-containing layer by supplying a second reactant gas including a saturated hydrocarbon into the chamber.

### CROSS-REFERENCES TO RELATED APPLICATION

The present application claims priority under 35 U.S.C. § 119(a) to Korean application number 10-2021-0119637, filed on Sep. 8, 2021, in the Korean Intellectual Property Office, which is incorporated herein by reference in its entirety.

### BACKGROUND

### 1. Technical Field

Various embodiments generally relate to a method for forming a graphene barrier layer for a semiconductor device, and more particularly, to a method of forming a barrier thin film including a graphene layer capable of reducing the contact resistance of a metal interconnect.

### 2. Related Art

A barrier layer or a barrier metal layer is a layer that is formed on the sidewall of each of a contact-target portion and a contact hole before formation of a metal interconnect (plug). This barrier layer serves to prevent stress, silicon diffusion and electron transfer between the metal interconnect and the contact while improving the contact characteristics between the metal interconnect (plug) and a dielectric layer/contact-target portion.

Conventionally, a titanium layer/titanium nitride layer (Ti/TiN), obtained by forming a titanium layer in a contact hole through which a contact-target portion is exposed and forming a titanium nitride layer on the titanium layer, is mainly used as a barrier layer.

However, the barrier layer having this structure is formed to have a thickness of 50 Å or more, and thus has a high Schottky barrier due to the large thickness. Accordingly, the barrier layer tends to increase the contact resistance.

Meanwhile, graphene is a single-atom-thick sheet of carbon atoms arranged in a hexagonal honeycomb pattern. For example, graphene may include one and more the single-atom-thick sheets. Graphene has characteristics such as high charge mobility reaching 200,000 cm²/Vs at room temperature, high mechanical strength, high flexibility, and high transmittance for visible light. Due to these characteristics, graphene is a very promising new material for ultra-high-speed nano semiconductors, transparent electrodes, and various sensors, etc.

However, in a conventional art, there are insufficient studies on a method of forming a barrier layer, which is capable of reducing the contact resistance of a semiconductor device, by using graphene. Thus, these studies are required.

### SUMMARY

To overcome the above-described technical problems, embodiments provide a method for forming a graphene barrier layer including: loading a substrate, which has a titanium-containing layer formed thereon, in a chamber of a substrate processing system, the chamber having a processing space formed therein; inducing nucleation on the titanium-containing layer by supplying a first reactant gas including a unsaturated hydrocarbon into the chamber; and forming a graphene layer on the titanium-containing layer by supplying a second reactant gas containing a saturated hydrocarbon into the chamber.

In an embodiment, the method may further include, after loading the substrate in the chamber, cleaning the substrate.

In an embodiment, the first reactant gas may include at least one unsaturated hydrocarbon selected from the group consisting of acetylene (C₂H₂), ethylene (C₂H₄), cyclopropane (C₃H₃), propene (C₃H₆), and benzene (C₆H₆), and the second reactant gas may include at least one saturated hydrocarbon selected from the group consisting of methane (CH₄), ethane (C₂H₆), propane (C₃H₈), butane C₄H₁₀), pentane (C₅H₁₂), and hexane (C₆H₁₄).

In an embodiment, each of the first and second reactant gases may be ionized into plasma before being supplied into the chamber of the substrate processing system, and the graphene layer may be formed by plasma-enhanced atomic layer deposition (PEALD) using the ionized first and second reactant gases.

Another embodiment provides a contact structure including a substrate, a patterned layer, a first barrier layer, a second barrier layer, a tungsten nucleation layer, and a tungsten bulk layer.

The patterned layer may include an interlayer dielectric layer. For example, the interlayer dielectric layer may include a titanium-containing layer. The patterned layer formed on the substrate to expose a selected portion of the substrate.

The first barrier layer may be formed on a surface of the patterned layer and the selected portion of the substrate and the first barrier layer may include a titanium layer. The second barrier layer may be formed on the first barrier layer and the second barrier layer may include a graphene layer. The tungsten nucleation layer may be formed on the second barrier layer. The tungsten bulk layer may be formed on the tungsten nucleation layer.

In the method for forming a graphene barrier layer for a semiconductor according to embodiments of the present disclosure, it is possible to form a graphene barrier layer by sequentially supplying the first and second reactant gases. The formed graphene barrier layer may reduce ohmic contact and contact resistance, and have increased adhesion to the tungsten layer, thereby providing a semiconductor device having excellent electrical properties.

In addition, it is possible to form a graphene barrier layer having a small thickness of 10 to 30 Å, thus reducing contact resistance compared to that in a semiconductor layer in which a titanium (Ti) layer and a titanium nitride (TiN) layer are formed.

### BRIEF DESCRIPTION OF THE DRAWINGS

FIG. 1 is a process diagram showing a method for forming a graphene barrier layer according to an embodiment.

FIG. 2 is a timing view showing the gas supply sequence and the plasma generation sequence in a method of forming a graphene barrier layer using plasma-enhanced atomic layer deposition (PEALD) according to an embodiment.

FIG. 3 is a conceptual view illustrating a substrate processing system that is used in the method for forming a graphene barrier layer according to an embodiment.

FIG. 4 is a conceptual view illustrating a contact structure according to an embodiment.

FIG. 5 is a flow chart showing a process for fabricating a contact structure according to Example 1.

### DETAILED DESCRIPTION

Hereinafter, embodiments of the present disclosure will be described in detail with reference to the accompanying drawings so that the present disclosure may be easily carried out by those skilled in the art to which the present disclosure pertains. However, since descriptions of the present disclosure are merely embodiments for structural or functional description, the scope of the present disclosure should not be interpreted as being limited to the embodiments disclosed herein. In other words, since the embodiments may be changed in various ways and have various forms, it is to be understood that the scope of the present disclosure includes equivalents that may embody the technical spirit of the present disclosure. In addition, objects or effects disclosed herein should not be construed as limiting the scope of the present disclosure, because disclosure thereof does not mean that a specific embodiment should include all or only such effects.

Terms used herein should be understood as follows.

Although the terms “first”, “second”, etc. may be used to herein to distinguish one component from another component, the components should not be limited by these terms. For example, a first component may be termed a second component, and similarly, a second component may also be termed a first component. It is to be understood that, when any component is referred to as being “connected” to another component, it may be connected directly to the other component or intervening components may be present. On the other hand, it is to be understood that, when any component is referred to as being “connected directly” to another component, there are no intervening components. Meanwhile, other expressions for describing the relationship between components, i.e., “between” and “directly between”, or “adjacent to” and “directly adjacent to,” should be interpreted in the similar manner.

It is to be understood that singular expressions include plural expressions unless specified otherwise in the context thereof. It is to be understood that the terms “include”, “have”, etc., are intended to denote the existence of mentioned characteristics, numbers, steps, operations, components, parts, or combinations thereof, but do not exclude the probability of existence or addition of one or more other characteristics, numbers, steps, operations, components, parts, or combinations thereof.

All terms used herein have the same meaning as commonly understood by one of ordinary skill in the art to which this disclosure pertains, unless defined otherwise. The terms used in general and defined in dictionaries should be interpreted as having meanings identical to those specified in the context of related technology. Unless definitely defined in the present disclosure, the terms should not be interpreted as having ideal or excessively formative meanings.

Hereinafter, the present disclosure will be described in detail.

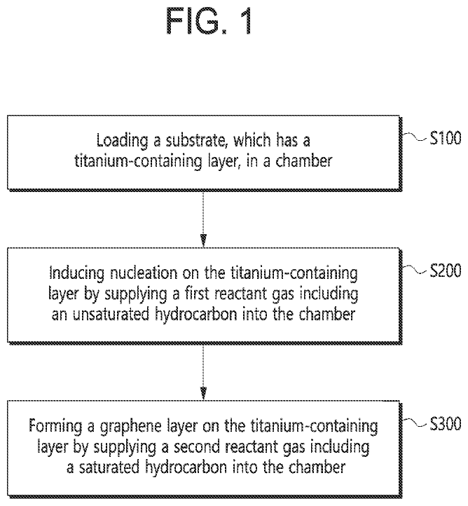

FIG. 1 is a process diagram showing a method for forming a graphene barrier layer according to an embodiment. Referring to FIG. 1, the method for forming a graphene barrier layer according to an embodiment includes steps of: (S100) loading a substrate, which has a titanium-containing layer formed thereon, in a chamber of a substrate processing system, the chamber having a processing space formed therein; (S200) inducing nucleation on the titanium-containing layer by supplying a first reactant gas including a unsaturated hydrocarbon into the chamber; and (S300) forming a graphene layer on the titanium-containing layer by supplying a second reactant gas containing a saturated hydrocarbon into the chamber.

In the method for forming a graphene barrier layer according to an embodiment, the graphene barrier layer may be formed on the substrate.

In order to form a graphene barrier layer on the substrate, a graphene barrier layer, which is a graphene layer as a barrier metal layer, is formed on the substrate using a plasma-enhanced atomic layer deposition process, an atomic layer deposition process, a chemical vapor deposition process, etc.

In step (S100) of loading (or mounting) the substrate, the substrate may be loaded in a chamber of a substrate processing system, which has a processing space formed therein.

The substrate that is used in the present disclosure may be made of at least one selected from among a variety of known materials used for fabricating semiconductor devices. Specifically, the substrate may be made of a material including is crystalline silicon, silicon oxide, silicon oxynitride, silicon nitride, strained silicon, silicon germanium, tungsten, titanium nitride, doped or undoped polysilicon, a doped or undoped silicon wafer, a patterned or non-patterned wafer, silicon on insulator (SOI), carbon-doped silicon oxide, silicon nitride, doped silicon, germanium, gallium arsenide, glass, sapphire, a low-k dielectric, or a mixture of two or more thereof.

In addition, the substrate may have a patterned layer formed thereon. The above-described patterned layer may be a barrier layer, that is, an interlayer dielectric layer already formed on the substrate before the graphene layer is deposited. The patterned layer may be in a thin layer form, and may include patterns such as trenches, holes, and vias. The barrier layer may function as an adsorption layer with the interlayer dielectric layer to suppress an unwanted reaction between the tungsten layer to be formed and the underlying layer.

According to an embodiment, the substrate on which the graphene layer is to be formed may be a substrate on which a titanium-containing layer, that is, a titanium layer, is formed. The titanium layer can promote the growth of graphene crystals by including titanium serving as a catalyst, and serves as a buffer layer to improve bonding strength between the graphene layer and the substrate. The titanium layer may promote graphene crystal growth by containing titanium serving as a catalyst, and serves as a buffer layer to improve adhesion between the graphene layer and the substrate.

The titanium layer may be formed on the substrate using a titanium precursor by a plasma-enhanced atomic layer deposition process, an atomic layer deposition process, a chemical vapor deposition process, or the like.

In addition, the method may further include, after the step of loading the substrate in the chamber, a step of cleaning the substrate. The cleaning of the substrate is performed to remove impurities remaining on the titanium-containing thin film, that is, the titanium layer, and may be performed by supplying an inert gas. In particular, the cleaning may be performed using a remote plasma generator (RPG) provided in the substrate processing system. Specifically, a cleaning gas may be ionized in the RPG and sprayed into the chamber to remove impurities. The cleaning gas that is used in the present disclosure may contain fluorine or chlorine. Specifically, the cleaning gas may include NF₃, C₂F₆, CF₄, F₂, CHF₃, SF₆, Cl₂, or a mixture of two or more thereof.

As the above-described substrate processing system, various types of apparatuses capable of simultaneously depositing layers on a plurality of substrates may be used. Contents regarding the substrate processing system will be described in more detail below.

In addition, the method may further include, after loading the substrate in the chamber of the substrate processing system and supplying the first reactant gas, a step of preheating the substrate to a predetermined process temperature. To this end, in this step, the substrate may be preheated to a temperature of 350 to 600° C.

The method for forming a graphene barrier layer according to an embodiment includes step (S200) of inducing nucleation on the substrate by supplying the first reactant gas.

The first reactant gas includes an unsaturated hydrocarbon, and the unsaturated hydrocarbon has a structure in which carbon atoms are linked together by two or three covalent bonds to form an ethylenically or acetylenically unsaturated group. This unsaturated hydrocarbon has a structure in which one sigma (σ) bond and one or two pi (π) bonds are formed. The unsaturated hydrocarbon has strong reactivity due to the π bond, and hydrogen atoms thereof may be dissociated from the carbon atoms when the gas is ionized into plasma, so that a carbon coating layer may be formed on the substrate.

The first reactant gas that is used in the present disclosure may be a gas including acetylene (C₂H₂), ethylene (C₂H₄), cyclopropane (C₃H₃), propene (C₃H₆), benzene (C₆H₆), or a mixture of two or more thereof. In particular, acetylene (C₂H₂) gas has a small molecular weight and particle size, so that it may be easily adsorbed into holes and cracks in the substrate or tungsten layer. In addition, acetylene gas has excellent filling performance, and is highly reactive, so that it may induce nucleation by reaction within a short time.

In addition, in this step, the step of supplying the first reactant gas may be performed one or more times to induce the unsaturated hydrocarbon to form carbon nucleation sites on the titanium layer. Then, the second reactant gas is supplied into the chamber to form a uniform sheet- or film-shaped graphene layer. That is, nucleation on the titanium layer is induced by the unsaturated hydrocarbon; and the step of supplying the first reactant gas is performed one or more times to increase the density of the nucleation sites which may correspond to the unsaturated hydrocarbon, thereby promoting nucleation and increasing the reactivity of the nucleation sites with the saturated hydrocarbon, thereby increasing the formation rate of the sheet-shaped graphene layer and the reaction rate and allowing the graphene layer to be easily formed even at a low temperature of 350 to 550° C., particularly 400 to 500° C. Accordingly, it is possible to increase the graphene crystal size, thereby providing a semiconductor device having excellent electrical properties.

Meanwhile, the method for forming a graphene barrier layer according to an embodiment includes, after inducing nucleation on the titanium layer of the substrate using the unsaturated to hydrocarbon, step (S300) of forming a graphene layer on the titanium-containing layer by supplying a second reactant gas containing a saturated hydrocarbon.

The second reactant gas includes a saturated hydrocarbon, and the saturated hydrocarbon reacts with carbon of the carbon coating layer formed by the unsaturated hydrocarbon to form graphene crystals. The second reactant gas includes a hydrocarbon having 1 to 6 carbon atoms. Specifically, the second reactant gas may be a gas including methane (CH₄), ethane (C₂H₆), propane (C₃H₈), butane (C₄H₁₀), pentane (C₅H₁₂), hexane (C₆H₁₄), or a mixture of two or more thereof. In particular, methane (CH₄) gas has the smallest molecular weight and particle size, and has excellent reactivity so that pure graphene crystals may grow.

In addition, in this step, the step of supplying the second reactant gas may be performed one or more times so that unreacted carbon atoms in the coating layer may be reacted, thereby forming a graphene layer on the substrate.

More specifically, graphene is a single-atom-thick sheet of carbon atoms arranged in a hexagonal honeycomb pattern. Accordingly, the graphene layer is formed one by one through linkages between aromatic nuclei having a hexagonal ring structure of carbon atoms.

In the method for forming a graphene barrier layer forming method according to an embodiment, when acetylene or cyclopropane gas, which is an unsaturated hydrocarbon, is supplied as the first reactant gas, hydrogen is dissociated from the carbon atoms by the remote plasma generator, and the remaining molecules having carbon-carbon bonds are ionized and serve as a precursor that induces linkages between the aromatic nuclei. In addition, methane gas, which is a saturated hydrocarbon, is ionized by the remote plasma generator to form a large amount of hydrogen ions, and these hydrogen ions collide with the carbon coating layer having carbon-carbon bonds, formed by the supply of acetylene gas, thereby inducing carbon-carbon bonds. Then, the hydrogen ions are dissociated, and thus the formation of cyclic carbon bonds may be promoted, thereby forming a graphene layer having a hexagonal lattice structure.

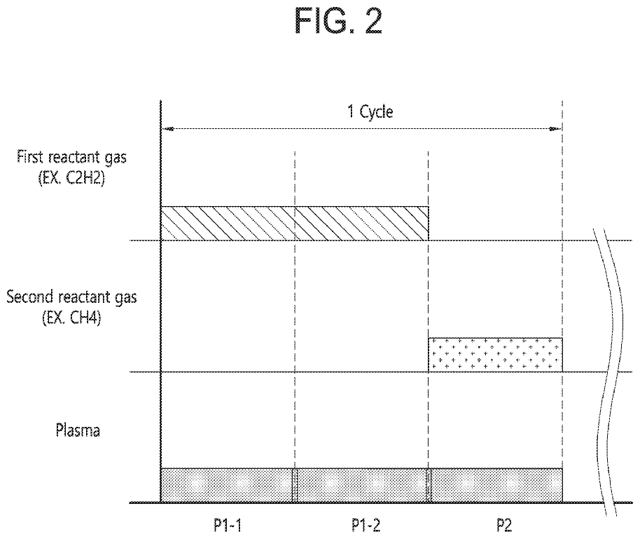

Accordingly, in the method for forming a graphene barrier layer according to an embodiment, as shown in FIG. 2, the step (P1-1 and P1-2) of supplying the first reactant gas to form a carbon coating layer on the substrate may be performed 2 or 3 times to form a carbon coating layer, and the step (P2) of supplying the second reactant gas may be performed once to form graphene crystals having a large particle size on the substrate, thereby improving electrical properties. Here, if the step of supplying the first reactant gas is performed once, it will be difficult to improve electrical properties because the crystal size is small, and if it the step of supplying the first reactant gas is performed more than three times, it will be difficult to expect additional crystal growth.

In addition, each of the first reactant gas and the second reactant gas may further include a carrier gas to control crystal growth and density, and the carrier gas may include hydrogen (H₂), argon (Ar), nitrogen (N₂), helium (He), or a mixture of two or more thereof. That is, the first reactant gas may be a mixed gas including 50 to 95 vol % of an unsaturated hydrocarbon and 5 to 50 vol % of a carrier gas, and the second reactant gas may be a mixed gas including 50 to 95 vol % of a saturated hydrocarbon and 5 to 5 to 95 vol % of a carrier gas.

As described above, when the coating layer is formed by supplying the first reactant gas and then the graphene layer is formed by supplying the second reactant gas, pure graphene crystals with a large particle size may be formed, thereby providing a semiconductor device having excellent electrical and chemical properties. In particular, the graphene layer formed by this method acts as a barrier layer, has a small thickness (less than 30 Å), may exhibit excellent physical properties, and may reduce contact resistance compared to that in a semiconductor device in which a titanium (Ti) layer and a titanium nitride (TiN) layer are formed. That is, the graphene layer formed by the above-described method has excellent adhesion to a tungsten layer to be formed thereon, and thus the Schottky barrier generated at the interface therebetween is low, and the graphene layer may exhibit low-resistance ohmic contact characteristics, thereby providing a semiconductor device having excellent electrical properties. In general, in a semiconductor device in which a titanium (Ti) layer and a titanium nitride (TiN) layer are formed, the thickness of the titanium nitride layer exceeds 50 Å.

In addition, in the method for forming a graphene barrier layer according to an embodiment, in order to control the thickness of the graphene barrier layer, the unit cycle including the step of inducing nucleation and the step of forming the graphene layer may be performed one or more times, and it may be performed for 3 or more cycles. The graphene layer formed by the above-described method may have a thickness of 10 to 30 Å.

In addition, the method may further include, after forming the graphene layer, a step of heat-treating the substrate having the graphene layer formed thereon, at a temperature of 450 to 1100° C. for 0.3 to 5 minutes. The heat treatment may be performed in a vacuum state or in an inert gas atmosphere, thereby preventing oxidation of the graphene layer. The heat-treated substrate may be cooled.

Meanwhile, in the method for forming a graphene barrier layer according to an embodiment, the graphene barrier layer may be formed on the substrate using a substrate processing system 1 having the structure described below.

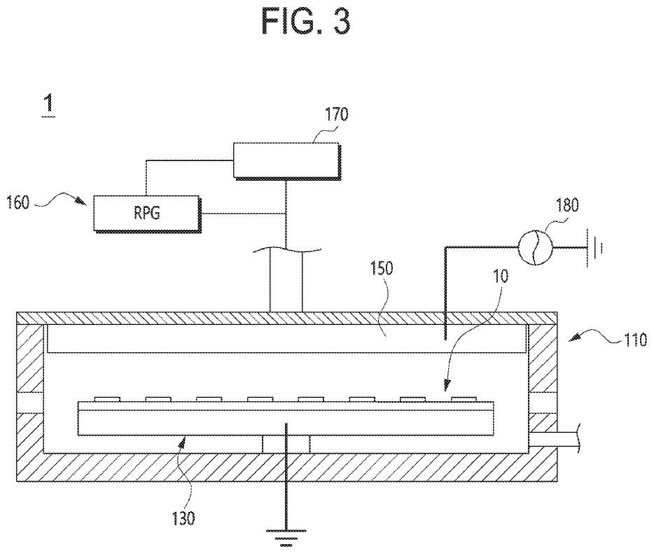

Specifically, as shown in FIG. 3, the substrate processing system 1 has a structure including a chamber 110, a substrate support 130, a gas supply unit 150, a remote plasma generator 160, a gas storage unit 170, and a plasma power supply unit 180.

The chamber 110 may be configured to provide a predetermined reaction space and to keep the reaction space airtight. For example, the chamber 110 may include a flat bottom portion, a side wall portion extending upward from the flat bottom portion, and a lid positioned at an upper end of the side wall portion. In this regard, the flat bottom portion may have the same shape as that of the lid. For example, the flat bottom portion and the lid may be manufactured in a circular shape or various shapes other than the circular shape. The chamber 110 may have a reaction space enclosed by the flat bottom portion, the side wall portion and the lid. Here, the reaction space of the chamber 110 may correspond to a space in which plasma generated from each of the reactant gases, a titanium precursor gas, a tungsten precursor gas, a purge gas, hydrogen gas, and a cleaning gas is activated. Although not shown in FIG. 3, the chamber 110 may be connected with an exhaust pipe (not shown) for externally discharging the reactant gases, a titanium precursor gas, a tungsten precursor gas, a purge gas, hydrogen gas, and a cleaning gas from the reaction space.

The substrate support 130 may be provided in the lower portion of the chamber 110 so as to support the substrate 10. Although not specifically shown in the figure, the substrate support 120 may include a susceptor on which the substrate 10 is loaded, and a heater for controlling the temperature of the substrate 10. In addition, the substrate support 130 may be manufactured in a shape corresponding to the substrate 10, without being particularly limited thereto. In addition, the substrate support 130 may be manufactured to be larger than the substrate 10, and one or more substrates may be disposed to thereon. A driving unit (not shown) for raising or lowering the substrate support 130 may be provided beneath the substrate support 120. For example, when the substrate 10 is loaded on the substrate support 130, the driving unit (not shown) may raise the substrate support 120 to be close to the gas supply unit 150.

The gas supply unit 150 is installed on the upper side of the chamber to perform the process and is configured to receive a gas from the gas storage unit 170 and supply the gas into the chamber. The gas supply unit may be configured in various ways depending on the process and the gas supply method. The gas supply unit may be configured to inject each of the reactant gases, a titanium precursor gas, a tungsten precursor gas, a purge gas, hydrogen gas, and a cleaning gas to the lower side of the chamber 110. The gas supply unit may have a plurality of holes for injecting the reactant gases, a tungsten precursor gas, a purge gas, hydrogen gas, and a cleaning gas, respectively.

The remote plasma generator (RPG) 160 may receive each of the reactant gases, a tungsten precursor gas, and a cleaning gas from the gas storage unit 170, ionize the received gas, and supply each of the reactant gases, titanium precursor gas, tungsten precursor gas, or cleaning gas to the chamber through the gas supply unit.

The gas storage unit 170 may include a plurality of storage tanks for storing the reactant gases, a tungsten precursor gas, a purge gas, hydrogen gas, and a cleaning gas, respectively, and may supply each of the tungsten precursor gas, purge gas, hydrogen gas, and cleaning gas to the gas supply unit 150.

Power may be applied to the substrate processing system 1 to perform the process, and the substrate processing system 1 may include a plasma power supply unit 180. The plasma power supply unit 180 may apply power to the gas injector 130 (or susceptor) provided in the chamber 110 in order to generate plasma from each of the process gases (e.g., reactant gases and cleaning gas) injected into the chamber 110.

The plasma power supply unit 180 may include a high-frequency (HF) plasma power supply member and a low-frequency (LF) plasma power supply member. The plasma power supply unit may be configured to provide upper-portion power by applying HF power or LF power to the gas supply unit 150, and to provide lower-portion power by grounding the substrate support 130. Accordingly, the power applied from the plasma power supply may be dual-frequency power including high-frequency (HF) power and low-frequency (LF) power. The high frequency (HF) power supply may be 5 MHz to 60 MHz, for example, 13.56 MHz, but is not particularly limited thereto. The high-frequency (HF) may be 5 MHz to 60 MHz, for example, 13.56 MHz, without being particularly limited thereto. In addition, the low-frequency (LF) power may be 100 kHz to 5 MHz, or 100 kHz to 2 MHz, for example, 430 kHz, without being particularly limited thereto.

Therefore, in the method for forming a graphene barrier layer according to an embodiment, the reactant gases may be supplied onto the substrate using the substrate processing system described above, and the graphene layer may be formed using plasma-enhanced atomic layer deposition (PEALD).

According to the method for forming a graphene barrier layer according to an embodiment, it is possible to reduce ohmic contact and contact resistance by sequentially supplying the first reactant gas and the second reactant gas, and increase the adhesion of the graphene barrier layer to the tungsten layer, thereby providing a semiconductor device having excellent electrical properties.

In addition, since it is possible to form a barrier layer including a thin graphene layer, it is possible to reduce contact resistance compared to that in a semiconductor device in which a titanium (Ti) layer and a titanium nitride (TiN) layer are formed.

Meanwhile, another embodiment provides a contact structure for a semiconductor device including the graphene layer, formed by the above-described method, as a barrier layer.

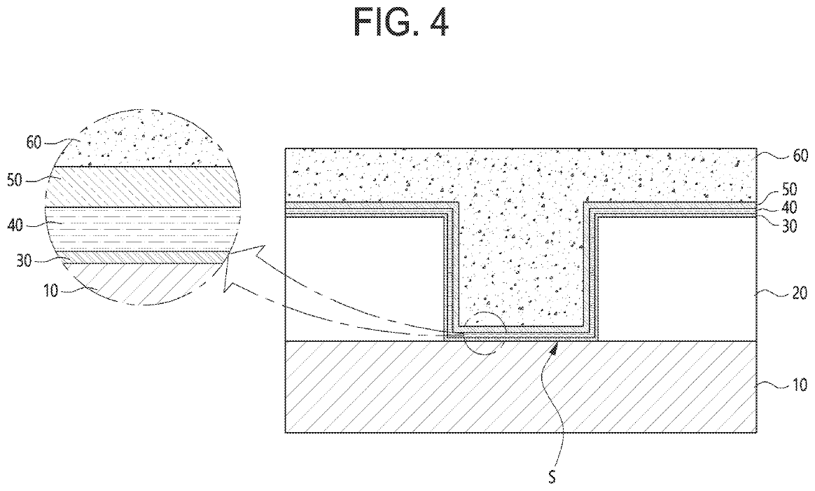

Referring to FIG. 4, the contact structure may have a structure including a substrate 10, a patterned layer 20 including an interlayer dielectric layer such as a titanium-containing layer, a first barrier layer 30, a second barrier layer 40, a tungsten nucleation layer 50, and a tungsten bulk layer 60.

The patterned layer 20 may include an interlayer dielectric layer. For example, the interlayer dielectric layer may include a titanium-containing layer. The patterned layer 20 formed on the substrate 10 to expose a selected portion “S” of the substrate 10.

The first barrier layer 30 may be formed on a surface of the patterned layer and the selected portion S of the substrate and the first barrier layer 30 may include a titanium layer. For example, the first barrier layer includes unsaturated hydrocarbon including at least one of acetylene (C₂H₂), ethylene (C₂H₄), cyclopropane (C₃H₃), propene (C₃H₆), and benzene (C₆H₆). The second barrier layer 40 may be formed on the first barrier layer 30 and the second barrier layer 40 may include a graphene layer. For example, the second barrier layer includes saturated hydrocarbon including at least one of methane (CH₄), ethane (C₂H₆), propane (C₃H₈), butane C₄H₁₀), pentane (C₅H₁₂), and hexane (C₆H₁₄). The tungsten nucleation layer 50 may be formed on the second barrier layer 40. The tungsten bulk layer 60 may be formed on the tungsten nucleation layer 50.

The contact structure may reduce ohmic contact and contact resistance, and exhibits excellent electrical properties by including, as the barrier layer, a graphene layer having excellent adhesion to the tungsten layer.

Hereinafter, the present disclosure will be described in more detail with reference to examples. However, the following examples are only specific examples of the present disclosure and are not intended to limit the scope of the present disclosure.

### Example 1

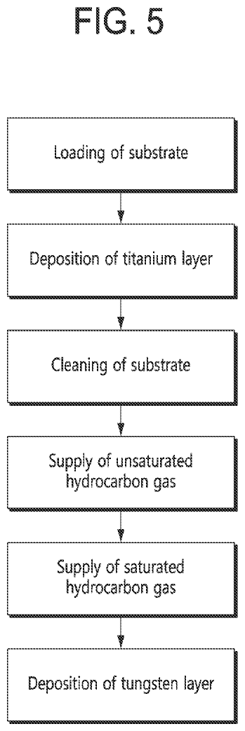

A contact structure was fabricated according to the process shown in FIG. 5. To this end, a titanium buffer layer was formed by depositing titanium on a silicon substrate having an interlayer dielectric layer formed thereon. Specifically, the titanium buffer layer was formed by supplying a titanium precursor such as tetrakis(dimethylamino)titanium and performing an atomic layer deposition process. A cleaning gas containing NF₃ was ionized into plasma through a remote plasma generator (RPG) of a substrate processing system and supplied into a chamber of the substrate processing system, thus removing impurities remaining on the titanium buffer layer formed on the substrate.

Using a substrate processing system having a structure as shown in FIG. 3, an unsaturated hydrocarbon gas including acetylene was supplied to a remote plasma generator in which it was ionized (or activated). The ionized unsaturated hydrocarbon gas was supplied into the chamber having the impurity-removed substrate loaded therein, thereby inducing nucleation on the titanium buffer layer. Here, nucleation was induced by repeating a cycle of supplying the unsaturated hydrocarbon gas a total of two times. Next, a saturated hydrocarbon gas including methane was ionized into plasma, and the ionized saturated hydrocarbon gas was supplied once to the titanium layer on which nucleation has been induced, and was then allowed to react at a temperature of 450 to 550° C., thus forming a graphene layer.

The unit cycle including nucleation induction and saturated hydrocarbon gas supply was repeated a total of three times.

Tungsten hexafluoride gas, diborane gas, and hydrogen gas were sequentially supplied, and a purge gas was supplied for each step, thereby forming a tungsten nucleation layer. A tungsten bulk layer was formed on the surface of the tungsten nucleation layer using tungsten hexafluoride gas and hydrogen gas, thereby fabricating a contact structure.

### Example 2

A contact structure was constructed in the same manner as in Example 1, except that the cycle of supplying the unsaturated hydrocarbon gas including acetylene was performed only once.

### Comparative Example 1

A titanium nitride layer was deposited by a chemical vapor deposition process using titanium tetrachloride and ammonia as reactant gases. Thereafter, a contact structure was fabricated in the same manner as in Example 1.

### Comparative Example 2

A contact structure was fabricated in the same manner as in Example 1, except that only the unsaturated hydrocarbon gas including acetylene was supplied to form a graphene layer.

### Comparative Example 3

A contact structure was fabricated in the same manner as in Example 1, except that only the saturated hydrocarbon gas including methane was supplied to form a graphene layer.

### Experimental Example

(1) Evaluation of Physical Properties

The physical properties of the contact structures fabricated by the methods according to Example 1 and Comparative Example 1 were evaluated. As the physical properties, work function (unit: eV), the thickness (Å) of the barrier layer, and low-temperature reactivity between tungsten and silicon were evaluated. The results are shown in Table 1 below.

TABLE 1

| | Comparative | |
|---|---|---|
| | Example 1 | Example 1 |
| Work function (eV) | 4.3 to 4.65 | 4.7 to 4.8 |
| Thickness (Å) | 50 to 100 | 15 to 19 |
| Low-temperature reactivity | OK | OK |

As shown in Table 1 above, it was confirmed that the contact structure having the graphene layer exhibited a work function of 4.7 to 4.8 eV, whereas the contact structure having the titanium nitride layer exhibited a work function of 4.3 to 4.65 eV. This suggests that, because the graphene layer formed by the plasma atomic layer deposition method has a thickness of only 15 to 19 Å, it reduces contact resistance, allows low-resistance ohmic contact, and exhibits improved electrical properties due to its increased adhesion to the tungsten layer.

In addition, as a result of evaluating the reactivity between tungsten and silicon, it could be confirmed that they easily diffused to each other, suggesting that they had good reactivity with each other.

In addition, as a result of evaluating the work function of the contact structure fabricated by the method according to each of Example 2, Comparative Example 2 and Comparative Example 3, it could be confirmed that the work function was 4.65 to 4.7 eV for Example 2, 4.25 to 4.35 eV for Comparative Example 2, and 4.20 to 4.30 eV for Comparative Example 3. This suggests that the use of acetylene gas and methane gas has beneficial effects on the electrical properties of the contact structure.

What is claimed is:

1. A method for forming a graphene barrier layer comprising:
loading a substrate, which has a titanium-containing layer formed thereon, in a chamber of a substrate processing system, the chamber having a processing space formed therein;
inducing nucleation on the titanium-containing layer by supplying a first reactant gas comprising unsaturated hydrocarbon into the chamber; and
to forming a graphene layer on the titanium-containing layer by supplying a second reactant gas comprising saturated hydrocarbon into the chamber.

2. The method of claim 1, further comprising cleaning the substrate after loading the substrate in the chamber.

3. The method of claim 1, wherein the unsaturated hydrocarbon includes at least one of acetylene (C₂H₂), ethylene (C₂H₄), cyclopropane (C₃H₃), propene (C₃H₆), and benzene (C₆H₆).

4. The method of claim 1, wherein the saturated hydrocarbon includes at least one of methane (CH₄), ethane (C₂H₆), propane (C₃H₈), butane C₄H₁₀), pentane (C₅H₁₂), and hexane (C₆H₁₄).

5. The method of claim 1, wherein the graphene layer is formed by sequentially supplying the first and second reactant gases, ionized into a plasma state, into the chamber of the substrate processing system.

6. The method of claim 1, wherein each of the inducing the nucleation and the forming the graphene layer includes:
supplying each of the first and second reactant gases at least once.

7. The method of claim 1, wherein repeating the inducing the nucleation and the forming the graphene layer continuously at least once.

8. The method of claim 1, wherein the graphene layer has a thickness of 10 to 30 Å.

9. A contact structure, comprising:
a substrate;
a patterned layer formed on the substrate to expose a selected portion of the substrate, the patterned layer including an interlayer dielectric layer;
a first barrier layer formed on a surface of the patterned layer and the selected portion of the substrate, the first barrier layer including a titanium layer;
a second barrier layer formed on the first barrier layer, the second barrier layer including a graphene layer;
a tungsten nucleation layer formed on the second barrier layer; and
a tungsten bulk layer formed on the tungsten nucleation layer.

10. The contact structure of claim 9,
wherein the first barrier layer includes unsaturated hydrocarbon including at least one of acetylene (C₂H₂), ethylene (C₂H₄), cyclopropane (C₃H₃), propene (C₃H₆), and benzene (C₆H₆).

11. The contact structure of claim 9,
wherein the second barrier layer includes saturated hydrocarbon including at least one of methane (CH₄), ethane (C₂H₆), propane (C₃H₈), butane C₄H₁₀), pentane (C₅H₁₂), and hexane (C₆H₁₄).
